(19) United States
(12) Patent Application Publication
(10) Pub. No.: US 2005/0099776 A1
(43) Pub. Date: May 12, 2005

(54) Passive thermal switch

(76) Inventors: Liang A. Xue, Canton, OH (US); Merrill M. Jackson, Tucson, AZ (US); Kenyon Kehl, Tucson, AZ (US); Edward M. Down, Tucson, AZ (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/712,471

(22) Filed: Nov. 12, 2003

(51) Int. Cl. H05K 7/20

(52) U.S. Cl. 361/700

(57) ABSTRACT

A passive thermal switch assembly simply, easily, and inexpensively controls electronic system component temperatures within normal operating ranges during normal system operations, and reduces heat dissipation from the system during a cold startup, to thereby enable a relatively rapid component temperature rise. The passive thermal switch includes a heat pipe and a thermally activated switch coupled to the condenser end of the heat pipe. The switch thermally couples and decouples the heat pipe from a heat sink based on the temperature of a contact within the switch.

### FIELD OF THE INVENTION

The present invention relates to passive heat removal from an electronic system and, more particularly, to a passive thermal switch assembly that thermally couples and decouples electronic devices to and from a heat sink, respectively.

### BACKGROUND OF THE INVENTION

Electronic systems, assemblies, and subassemblies are being designed with increasingly higher density circuit packages. There may be several reasons for this. Among the reasons that are most notably significant in aerospace applications are the reduced volume and/or area, the reduced weight, and/or the increased functionality that many high density circuit packages accord. These high density circuit packages may also generate more heat, both on a unit volume basis, at the system or subsystem level, and on a unit area basis, at the circuit board level. Thus, heat removal capabilities may need to be increased for certain systems, subsystems, and/or circuit boards to keep component temperatures within specified ranges.

Many electronic systems, such as those implemented in an aerospace environment, may be subjected to potentially harsh environmental conditions, such as relatively low temperatures. Thus, when these systems are shutdown, the electronic component temperatures may also be subject to relatively low temperatures, which may fall below normal operating temperature ranges. As a result, when these systems are subsequently energized (e.g., “cold started”), the components may need to be heated up rapidly to within the normal operating temperature ranges.

As may be apparent from the above, electronic systems that include high density circuit packages, and that are exposed to relatively low temperatures, may need to implement disparate thermal energy dissipation strategies. In particular, when the systems are energized and operating, the system may need to implement a high heat dissipation strategy by, for example, increasing heat conduction away from circuit components within the system. Conversely, when the system undergoes a cold start, the system may need to implement a low heat dissipation strategy by, for example, reducing heat conduction away from circuit components within the system.

Hence, there is a need for a system and method of thermal management in electronic systems that can simply, easily, and inexpensively control system component temperatures within normal operating ranges during normal system operations, while reducing heat dissipation from the system during a cold startup, to thereby enable a relatively rapid component temperature rise. The present invention addresses this need.

### SUMMARY OF THE INVENTION

The present invention provides a passive thermal switch assembly that simply, easily, and inexpensively controls electronic system component temperatures within normal operating ranges during normal system operations, and that reduces heat dissipation from the system during a cold startup, to thereby enable a relatively rapid component temperature rise.

In one embodiment, and by way of example only, a passive thermal management switch assembly includes a heat pipe and a switch. The heat pipe has an evaporator end and a condenser end, and the switch is coupled to the heat pipe condenser end. The switch is comprised at least partially of a material having a shape or volume that varies with temperature.

In another exemplary embodiment, an electronic system includes a chassis, one or more circuit components, one or more heat pipes, and one or more switches. The circuit components are housed within the chassis. Each heat pipe has an evaporator end and a condenser end, and each heat pipe evaporator end is coupled to at least one of the circuit components. Each of the switches is coupled to a heat pipe condenser end, is comprised at least partially of a material having a shape or volume that varies with temperature, and is disposed adjacent the chassis, whereby each switch is selectively thermally coupled to, and thermally decoupled from, the chassis at a predetermined temperature.

Other independent features and advantages of the preferred passive thermal switch will become apparent from the following detailed description, taken in conjunction with the accompanying drawings which illustrate, by way of example, the principles of the invention.

### BRIEF DESCRIPTION OF THE DRAWINGS

FIG. 1 is a simplified cross section view of an exemplary electronic equipment enclosure that may incorporate one or more of the passive thermal switches of the present invention;

FIGS. 2 and 3 are perspective and side views, respectively, of an exemplary passive thermal switch assembly in accordance with a first embodiment of the present invention;

FIGS. 4 and 5 are perspective and side views, respectively, of an exemplary passive thermal switch assembly in accordance with an alternative embodiment of the present invention;

FIGS. 6 and 7 are perspective and side views, respectively, of an exemplary passive thermal switch assembly in accordance with yet another embodiment of the present invention;

FIGS. 8 and 9 are perspective and side views, respectively, of yet another exemplary passive thermal switch assembly;

FIG. 10 is a simplified schematic representation of still another alternative passive thermal switch; and

FIG. 11 is a simplified schematic representation of an exemplary heat pipe that may be used with the passive thermal switches of FIGS. 2-10.

### DETAILED DESCRIPTION OF A PREFERRED EMBODIMENT

Before proceeding with the detailed description, it should be appreciated that the following detailed description is merely exemplary in nature and is not intended to limit the invention or the application and uses of the invention. Furthermore, there is no intention to be bound by any theory presented in the preceding background or the following detailed description.

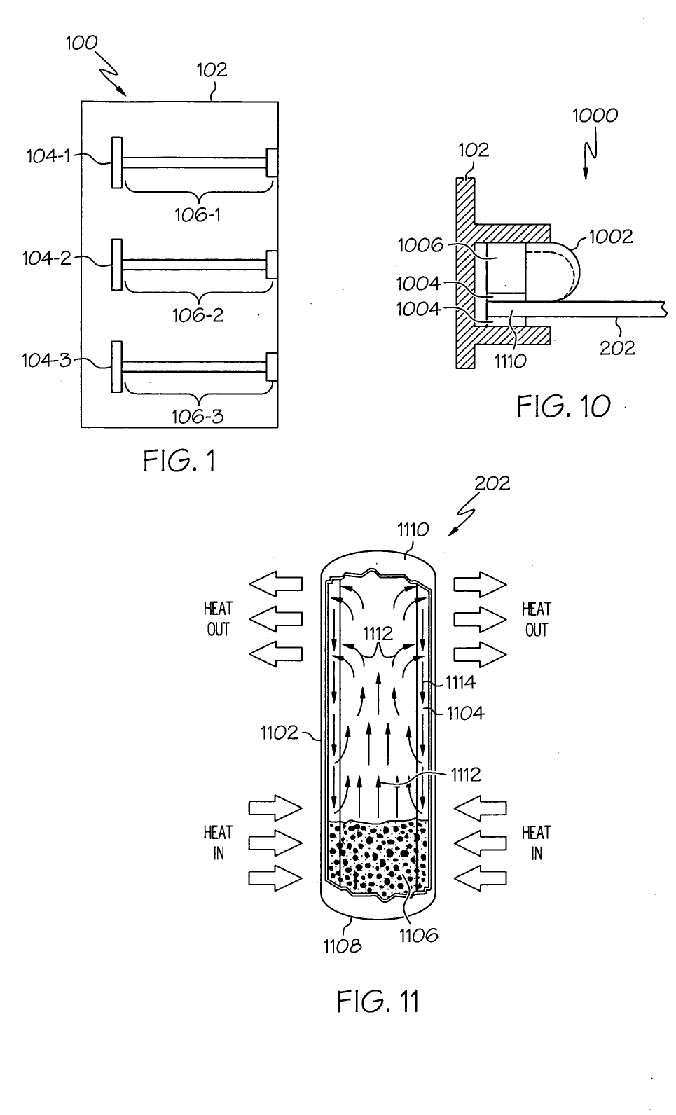

Turning now to the description and with reference first to FIG. 1, a simplified cross section view of an exemplary electronic equipment enclosure 100 is depicted. The enclosure 100 includes a chassis 102, in which are mounted a plurality of electronic components 104. In the depicted embodiment, the electronic components include a plurality of electronic circuit boards 104 (e.g., 104-1, 104-2, 104-3).

Although three circuit boards 104 are depicted, it will be appreciated that this is done merely for clarity and simplicity of representation, and the present invention is not limited to use with this number of circuit boards. Moreover, it will be appreciated that the electronic components are not limited to those configured as electronic circuit boards 104, but could be configured, for example, as individual electronic components, electronic circuit packages, or one or more groups of individual components. Furthermore, it will be appreciated that the circuit components 104 may be mounted in the chassis 102 using any one of numerous mounting configurations.

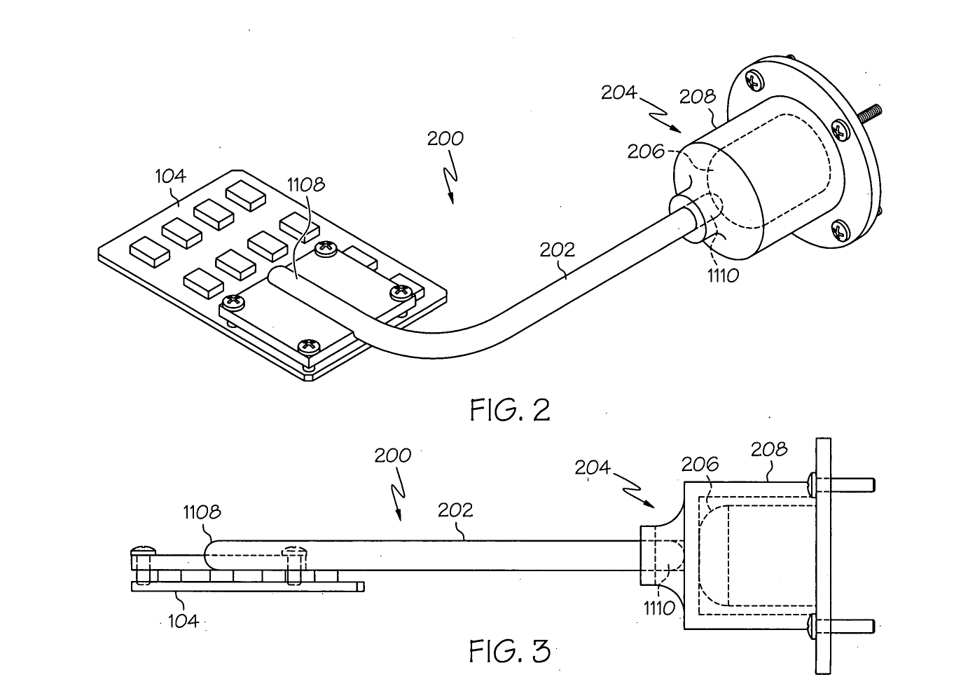

As FIG. 1 also shows, a plurality of passive thermal switch assemblies 106 (e.g., 106-1, 106-2, 106-3) are coupled between the circuit components 104 and the chassis 102, or other heat sink (not shown in FIG. 1). In the depicted embodiment, only one thermal switch assembly 106 is shown coupled to each circuit component 104. However, it will be appreciated that more than one thermal switch assembly 106 could be coupled to each circuit component 104, and that a single thermal switch assembly 106 is depicted merely for the sake of clarity. It will additionally be appreciated that each circuit component 104 need not have the same number of thermal switch assemblies 106 coupled thereto, and that some circuit components 104, depending on the amount of heat each generates, may not have any thermal switch assemblies 106 coupled thereto. Turning now to FIGS. 2-8, a detailed description of various exemplary embodiments of a passive thermal switch assembly 106 will be provided.

A perspective view and a side view of an exemplary passive thermal switch assembly 200 is shown in FIGS. 2 and 3, respectively, and includes a heat pipe 202 and a switch 204. The heat pipe 202 may be any one of numerous types of known heat pipes including, for example, conventional and variable conductance heat pipes. A simplified representation of a conventional heat pipe 202 is shown in FIG. 11, to which reference should now be made, as its operation is explained. Before doing so, however, it should be appreciated that the depicted and described heat pipe 202 is merely exemplary of any one of numerous types and configurations of heat pipes that can be used to implement the passive-thermal switch 200. The description is provided merely for completeness of disclosure.

A heat pipe 202 generally includes a sealed casing 1102, a wick 1104, and a working fluid 1106. The casing 1102 has two ends, one of which is referred to as the evaporator end 1108, and the other of which is referred to as the condenser end 1110. When heat is transferred into the heat pipe evaporator end 1108, the working fluid 1106 is vaporized, which absorbs the latent heat of vaporization. The vapor 1112 flows toward the condenser end 1110, where it is condensed and rejects the latent heat. The condensed working fluid 1114 then flows back to the evaporator end 1108, via the wick 1104, which may be, for example, a mesh or sintered powder.

A heat pipe 202 can be designed to selectively commence and cease the evaporation/condensation cycle described above at a predetermined temperature. Generally, the characteristics of the working fluid 1106, such as its vaporization and condensation temperatures, will determine this temperature.

Returning now to FIGS. 2 and 3, it is seen that the heat pipe evaporator end 1108 is coupled to one or more of the circuit components 104, and the heat pipe condenser end 1110 is coupled to the switch 204. The switch 204 includes at least two contacts, a first contact 206 and a second contact 208. In the depicted embodiment, the first contact 206 is coupled to the heat pipe condenser end 1110, and the second contact 208 is adapted to couple to a heat sink, such as the chassis 102, the external environment, or a dedicated heat sink.

In the embodiment depicted in FIGS. 2 and 3, the first contact 206 surrounds a the second contact 208, and is constructed, at least in part, of a shape memory metal or metal alloy such as, for example, nickel-titanium, copper-zinc-aluminum, or iron-manganese-silicon. The second contact 208 is constructed, at least in part, of a metal having good heat transfer characteristics such as, for example, copper or aluminum. It will be appreciated that the second contact 208 could also, though not preferably, be formed of a shape memory metal or metal alloy.

Shape memory metals and metal alloys, such as those delineated above, change shape with variations in temperature. Thus, the first 206 and second 208 contacts are disposed adjacent one another, and are configured such that when the first contact 206 is at or below a predetermined temperature the first 206 and second 208 contacts are thermally decoupled from one another. As the first contact 206 heats up, it undergoes a shape change such that at or above the predetermined temperature the first contact 206 is thermally coupled to the second contact 208. In the context of the depicted embodiment, this occurs when the first 206 and second 208 contacts engage one another.

In the context of the electronic equipment enclosure 100, when the circuit components 104 are at or below the predetermined temperature, such as during a cold startup, the first 206 and second 208 switch contacts are thermally decoupled from one another. As such, the heat pipe 202 is thermally decoupled from the heat sink, and the circuit components 104 will begin heating up. As the circuit components 104 heat up, heat is transferred to the heat pipe 202, and from the heat pipe to the first contact 206, causing the first contact 206 to undergo a shape change. When the circuit components 104 reach the normal operating range, the first contact 206 preferably reaches the predetermined temperature and its shape is changed sufficiently to cause it to engage, and thereby be thermally coupled to, the second contact 208. With the first 206 and second 208 contacts thermally coupled together, heat is efficiently transferred from the circuit components 104 to a heat sink.

It will be appreciated that the switch 204 may be, and preferably is, configured to selectively thermally couple to, and thermally decouple from, the chassis 102 at a predetermined temperature that will maintain the electronic circuit components 104 within the normal operating range while energized and operating. It will additionally be appreciated that the switch 204 may be configured such that it may be implemented as either a normally open switch 204, as described above, or as a normally closed switch.

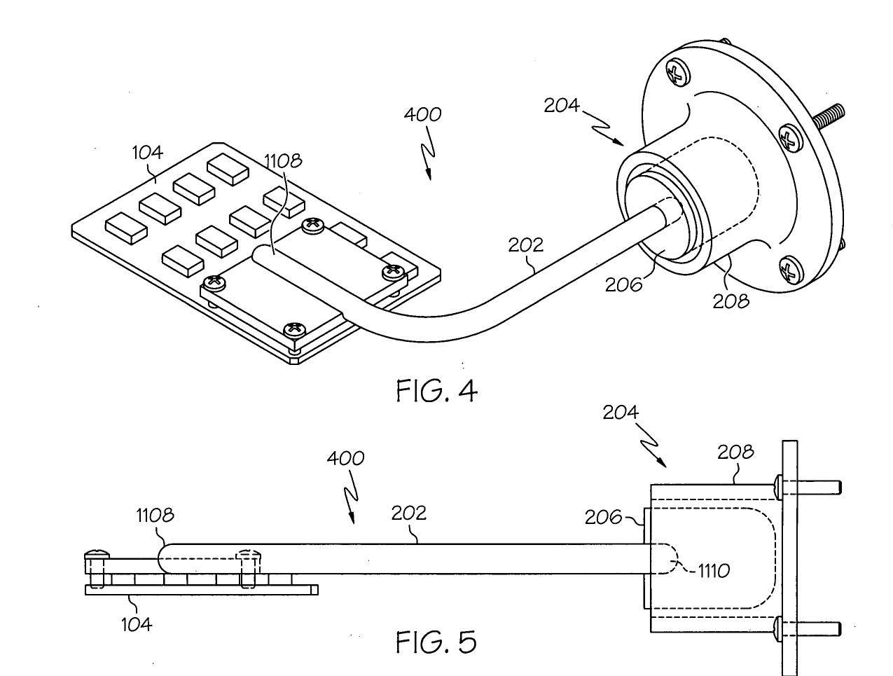

With reference now to FIGS. 4 and 5, an exemplary alternative embodiment of a passive thermal switch assembly 400 is shown, in which like reference numerals refer to like parts of the previous embodiment. This embodiment is similar to the previously described thermal switch assembly 200, though the switch 204 is configured differently. In particular, similar to the previous embodiment, the heat pipe evaporator end 1108 is coupled to one or more of the circuit components 104, the heat pipe condenser end 1110 is coupled to the switch first contact 206, and the switch second contact 208 is thermally coupled to the heat sink. However, in this embodiment, the second contact 208 at least partially surrounds the first contact 206. Moreover, the switch 204 is constructed of a bi-metal pair, in which the first contact 206 is constructed at least partially of a first metal having a first coefficient of thermal expansion, and the second contact 208 is constructed at least partially of a second metal having a second coefficient of thermal expansion. For example, in a particular preferred embodiment, the first contact 206 is constructed at least partially of copper, and the second contact 208 is constructed at least partially of iron. It will be appreciated that various other bi-metal pairs can be used for the switch including, but not limited to, aluminum and nickel, zinc and nickel, zinc and aluminum, copper and molybdenum, and aluminum and iron.

With the embodiment of FIGS. 4 and 5, when the circuit components 104 are at or below the predetermined temperature, such as during a cold startup, the first 206 and second 208 switch contacts are thermally decoupled from one another. As such, the heat pipe 202 is thermally decoupled from the heat sink, and the circuit components 104 will begin heating up. As the circuit components 104 heat up, heat is transferred to the heat pipe 202, and from the heat pipe 202 to the first contact 206, causing the first contact 206 to undergo thermal expansion. Because of the differing materials of construction, the first 206 and second 208 contacts expand at different rates, with the expansion rate of the first contact 206 being significantly higher than that of the second contact 208.

As with the prior embodiment, when the circuit components 104 reach the normal operating range, the first contact 206 preferably reaches a temperature at which its thermal expansion is sufficient to cause it to engage, and thereby be thermally coupled to, the second contact 208. With the first 206 and second 208 contacts thermally coupled together, heat is efficiently transferred from the circuit components 104 to the heat sink. In addition, as with the prior embodiment, the switch 204 may be configured such that it may be implemented as either a normally open switch, or a normally closed switch.

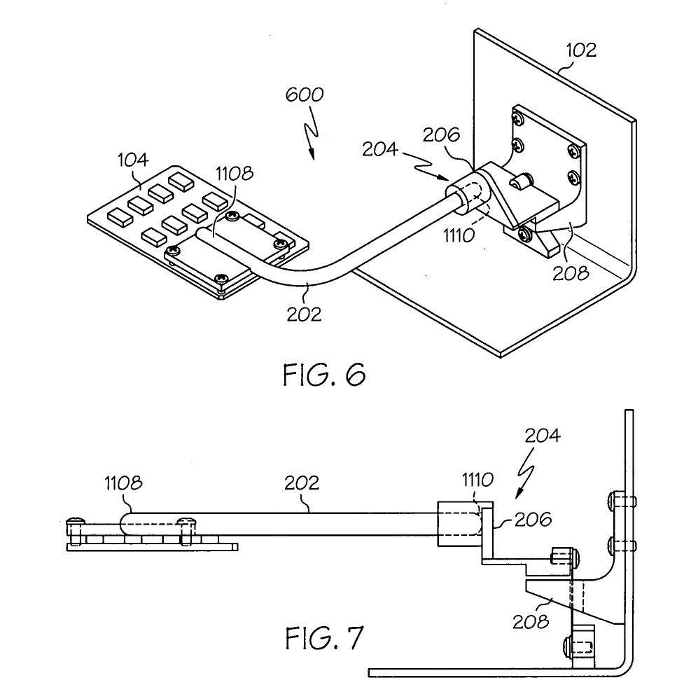

Yet another passive thermal switch embodiment 600 is shown in FIGS. 6 and 7, in which like reference numerals refer to like parts of the previous embodiments, and will now be described. This passive thermal switch 400 is similar to the previously described embodiments, in that the switch 204 has first 206 and second 208 contacts, the heat pipe evaporator end 1108 is coupled to one or more of the circuit components 104, and the heat pipe condenser end 1110 is coupled to the switch first contact 206. However, as will now be described, the configuration of the first 206 and second 208 switch contacts is significantly different than the two previous embodiments.

In the switch 204 of this third embodiment, the first 206 and second 208 contacts are disposed adjacent one another. However, neither switch contact 206, 208 at least partially surrounds the other switch contact 208, 206. Instead, the first 206 and second 208 contacts are each preferably configured as a plate. The first contact 206 is coupled to the heat pipe condenser end 1110, and the second contact 208 is coupled to a heat sink, such as the chassis 102. The switch 204 in the third embodiment additionally includes a tendon 602 that is coupled between the first contact 206 and another structure such as, for example, the chassis 102. The tendon 602 is preferably constructed, at least in part, of a shape memory metal or metal alloy. The first 206 and second 208 contacts may also be constructed, at least in part, of either a shape memory metal or metal alloy or a non-shape memory metal or metal alloy having good heat transfer characteristics. In a particular preferred embodiment, the first 206 and second 208 contacts are constructed of metal having good heat transfer characteristics such as, for example, aluminum or copper.

With the passive thermal switch 600 of FIGS. 6 and 7, when the circuit components 104 are at or below a predetermined temperature, such as during a cold startup, the switch 204 is configured such that the first 206 and second 208 switch contacts are thermally decoupled from one another. As such, the heat pipe 202 is thermally decoupled from the heat sink, and the circuit components 104 will begin heating up. As the circuit components 104 heat up, heat is transferred to the heat pipe 202, and from the heat pipe 202 to the first contact 206 and the tendon 602. This, in turn, causes the tendon 602 to heat up and begin changing its shape in a manner that the tendon 602 begins contracting, and moving the first contact 206 toward the second contact 208. When the circuit components 104 reach the normal operating range, the tendon 602 preferably reaches a temperature at which its shape is changed sufficiently to cause it to move the first contact 206 into engagement with, and thereby be thermally coupled to, the second contact 208. With the first 206 and second 208 contacts thermally coupled together, heat is efficiently transferred from the circuit components 104 to the chassis 102 (or other heat sink). As with the prior embodiments the switch 204 in this third embodiment may be implemented as either a normally open switch, or a normally closed switch.

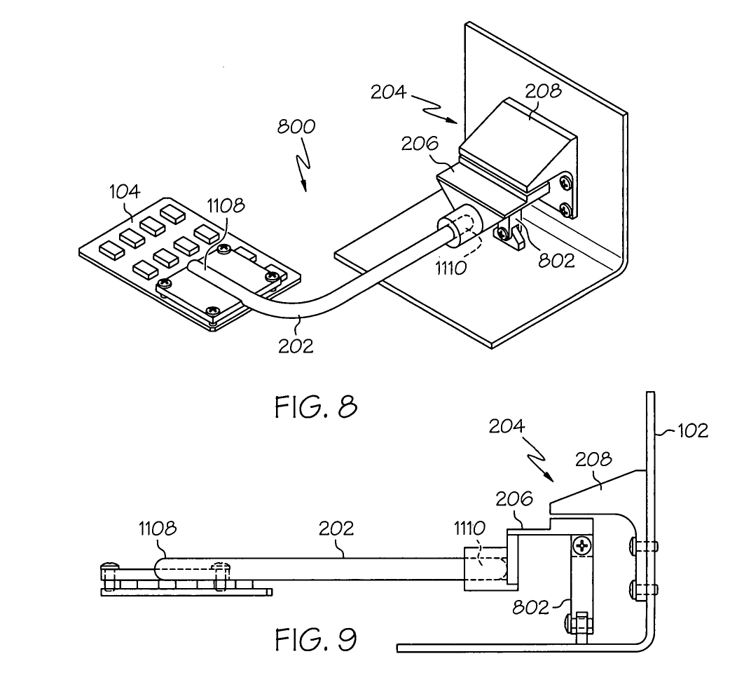

The passive thermal switch 600 shown in FIGS. 6 and 7, and described above, is configured such that the tendon 602 pulls the first 206 and second 208 contacts together as circuit component temperature increases. In another embodiment, which is shown in FIG. 8 and 9, the switch 204 is configured such that the switch contacts 206, 208 are pushed together. This passive thermal switch 800 is similar to the one shown in FIGS. 6 and 7, in that the switch 204 includes first 206 and second 208 contacts that are disposed adjacent one another, and are configured as a plate. The first contact 206 is coupled to the heat pipe condenser end 1110, and the second contact 208 is coupled to a heat sink, such as the chassis 102.

The switch 204 in this fourth embodiment additionally includes an expansion column 802 that is coupled between the first contact 206 and another structure such as, for example, the chassis 102. The expansion column 802 is preferably constructed, at least in part, of a shape memory metal or metal alloy. As with the other embodiment, the first 206 and second 208 contacts may also be constructed, at least in part, of either a shape memory metal or metal alloy or a non-shape memory metal or metal alloy having good heat transfer characteristics. In a particular preferred embodiment, the first 206 and second 208 contacts are constructed of metal having good heat transfer characteristics such as, for example, aluminum or copper.

With the passive thermal switch 800 of FIGS. 8 and 9, when the circuit components 104 are at or below a predetermined temperature, such as during a cold startup, the switch 204 is configured such that the first 206 and second 208 switch contacts are thermally decoupled from one another. As such, the heat pipe 202 is thermally decoupled from the heat sink, and the circuit components 104 will begin heating up. As the circuit components 104 heat up, heat is transferred to the heat pipe 202, and from the heat pipe 202 to the first contact 206 and the expansion column 802. This, in turn, causes the expansion column 802 to heat up and begin changing its shape in a manner that the expansion column 802 begins expanding, and moving the first contact 206 toward the second contact 208. When the circuit components 104 reach the normal operating range, the expansion column 802 preferably reaches a temperature at which its shape is changed sufficiently to cause it to move the first contact 206 into engagement with, and thereby be thermally coupled to, the second contact 208. With the first 206 and second 208 contacts thermally coupled together, heat is efficiently transferred from the circuit components 104 to the chassis 102 (or other heat sink). As with the prior embodiments the switch 204 in this fourth embodiment may be implemented as either a normally open switch, or a normally closed switch.

Turning now to FIG. 10, in which like reference numerals once again refer to like parts of the previous embodiments, another alternative passive switch embodiment will be described. This passive thermal switch 1000 includes a heat pipe 202 and switch 204. As with the prior embodiments, the heat pipe evaporator end 1108 is coupled to one or more circuit components 104, and the heat pipe condenser end is coupled to the switch 204. However, the switch 204 in this embodiment includes only a single contact 1002.

The single contact 1002 is formed of a shape memory metal or metal alloy, or a bimetallic pair. As such, it undergoes a shape or volume change as its temperature changes. This change in shape or volume causes the contact 1002 to be selectively thermally coupled to, and decoupled from, the heat sink. In the particular embodiment shown in FIG. 10 the heat pipe condenser end 1110 is mounted on the heat sink, via one or more thermal insulators 1004 and a wedge lock 1006. The contact 1002 is disposed adjacent to a heat sink (e.g., the chassis 102), such that it is thermally decoupled from the heat sink when the temperature of the contact 1002 is below a predetermined temperature value. When the temperature of the contact 1002 reaches the predetermined temperature value, however, it will be thermally coupled to the heat sink.

Thus, with the passive thermal switch 1000 of FIG. 10, when the circuit components 104 are at or below a predetermined temperature, such as during a cold startup, the switch 204 is configured such that the contact 1002 is thermally decoupled from the heat sink. As such, the heat pipe 202 is thermally decoupled from the heat sink (shown in phantom in FIG. 10), and the circuit components 104 will begin heating up. As the circuit components 104 heat up, heat is transferred to the heat pipe 202, and from the heat pipe 202 to the contact 1002. This, in turn, causes the contact 1002 to heat up and begin changing its shape or volume in a manner that the contact 1002 begins moving toward the heat sink. When the circuit components 104 reach the normal operating range, the contact 1002 preferably reaches a temperature at which its shape or volume is changed sufficiently to cause it to engage, and thereby be thermally coupled to, the heat sink. As a result, heat is efficiently transferred from the circuit components 104 to the heat sink.

It will be appreciated that the switch 204 in this fourth embodiment, as with the prior embodiments, may be implemented as either a normally open switch, or a normally closed switch. It will additionally be appreciated that the mounting configuration depicted in FIG. 10 is merely exemplary of one of numerous mounting configurations that can be used with the depicted passive thermal switch 1000. It will be further appreciated that more than one contact 1002 could be coupled to the heat pipe condenser end 1110. Moreover, it will be appreciated that the shape of the contact 1002 shown in FIG. 10 (e.g., a C-shape) is merely exemplary, and that numerous other shapes could be used.

The passive thermal switch assemblies described herein simply, easily, and inexpensively control electronic system component temperatures within normal operating ranges during normal system operations. The switches also reduce heat dissipation from the system during a cold startup, to thereby enable a relatively rapid component temperature rise.

While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A passive thermal switch assembly, comprising:
a heat pipe having an evaporator end and a condenser end; and
a switch coupled to the heat pipe condenser end, the switch comprised at least partially of a material having a shape or volume that varies with temperature.

2. The switch assembly of claim 1, wherein the switch comprises:
a first thermally conductive contact coupled to the heat pipe condenser end; and
a second thermally conductive contact disposed proximate the fist thermally conductive contact.

3. The switch assembly of claim 2, wherein the first and second thermally conductive contacts are selectively thermally coupled and thermally decoupled from one another in response to variations in temperature of either or both of the contacts.

4. The switch assembly of claim 2, wherein the first and second thermally conductive contacts at least partially engage one another when at least a portion of the first thermally conductive contact reaches a predetermined temperature.

5. The switch assembly of claim 2, wherein:
the first thermally conductive contact is comprised of a shape memory metal or shape memory metal alloy; and
the second thermally conductive contact is comprised of a non-shape memory metal or metal alloy, and is at least partially surrounded by at least a portion of the first thermally conductive contact.

6. The switch assembly of claim 2, wherein:
the first thermally conductive contact is comprised of a non-shape memory metal or metal alloy; and the second thermally conductive contact is comprised of a shape memory metal or shape memory metal alloy, and is disposed adjacent the first thermally conductive contact.

7. The switch assembly of claim 6, wherein the first and second thermally conductive contacts are selectively thermally coupled and thermally decoupled from one another in response to variations in temperature of either or both of the contacts.

8. The switch assembly of claim 6, wherein the first and second thermally conductive contacts selectively engage one another, at least partially, in response to variations in temperature of either or both of the contacts.

9. The switch assembly of claim 2, further comprising:
one or more conductive links, each conductive link having a fist end coupled to the first contact and a second end adapted to couple to a substantially fixed structure,
wherein each conductive link is comprised of a shape memory metal or metal alloy.

10. The switch of claim 2, wherein:
the first thermally conductive contact is comprised of a first metal having a first temperature coefficient of expansion; and
the second thermally conductive contact is comprised of a second metal having a second temperature coefficient of expansion that is different from the first temperature coefficient of expansion, and at least partially surrounds at least a portion of the first thermally conductive contact.

11. The switch assembly of claim 10, wherein the first and second thermally conductive contacts selectively engage one another, at least partially, in response to variations in temperature of either or both of the contacts.

12. The switch assembly of claim 10, wherein the first and second thermally conductive contacts at least partially engage one another when at least a portion of the first thermally conductive contact reaches a predetermined temperature.

13. The switch assembly of claim 1, wherein the material is a shape memory alloy.

14. The switch assembly of claim 13, wherein the shape memory alloy is selected from the group consisting of nickel-titanium, copper-zinc-aluminum, and iron-manganese-silicon.

15. The switch assembly of claim 1, wherein switch is comprised of two metals having different thermal coefficients of expansion.

16. The switch assembly of claim 15, wherein the two metals are selected from the group of pairs consisting of aluminum and nickel, zinc and nickel, zinc and aluminum, copper and iron, copper and molybdenum, and aluminum and iron.

17. An electronic equipment enclosure, comprising:
a chassis;
one or more circuit components housed within the chassis;
one or more heat pipes each having an evaporator end and a condenser end, each heat pipe evaporator end coupled to at least one of the circuit components; and
one or more switches coupled to each heat pipe condenser end, each switch comprised at least partially of a material having a shape or volume that varies with temperature and disposed adjacent the chassis, whereby each switch is selectively thermally coupled to, and thermally decoupled from, the chassis at a predetermined temperature.

18. The system of claim 17, wherein each switch comprises:
a first thermally conductive contact coupled to the heat pipe condenser end; and
a second thermally conductive contact disposed proximate the first thermally conductive contact.

19. The system of claim 18, wherein the first and second thermally conductive contacts are selectively thermally coupled and thermally decoupled from one another in response to variations in temperature of either or both of the contacts.

20. The system of claim 18, wherein the first and second thermally conductive contacts at least partially engage one another when at least a portion of the first thermally conductive contact reaches a predetermined temperature.

21. The system of claim 18, wherein:
the first thermally conductive contact is comprised of a shape memory metal or shape memory metal alloy; and
the second thermally conductive contact is comprised of a non-shape memory metal or metal alloy, and is at least partially surrounded by at least a portion of the first thermally conductive contact.

22. The system of claim 18, wherein:
the first thermally conductive contact is comprised of a shape memory metal or shape memory metal alloy; and
the second thermally conductive contact is comprised of a non-shape memory metal or metal alloy, and is disposed adjacent the first thermally conductive contact.

23. The system of claim 22, wherein the first and second thermally conductive contacts are selectively thermally coupled and thermally decoupled from one another in response to variations in temperature of either or both of the contacts.

24. The system of claim 22, wherein the first and second thermally conductive contacts selectively engage one another, at least partially, in response to variations in temperature of either or both of the contacts.

25. The system of claim 18, further comprising:
one or more conductive links, each conductive link having a first end coupled to the first contact and a second end adapted to couple to a substantially fixed structure,
wherein each conductive link is comprised of a shape memory metal or metal alloy.

26. The system of claim 18, wherein:
the first thermally conductive contact is comprised of a first metal having a first temperature coefficient of expansion; and
the second thermally conductive contact is comprised of a second metal having a second temperature coefficient of expansion that is different from the first temperature coefficient of expansion, and at least partially surrounds at least a portion of the first thermally conductive contact.

27. The system of claim 26, wherein the first and second thermally conductive contacts selectively engage one another, at least partially, in response to variations in temperature of either or both of the contacts.

28. The system of claim, 26 wherein the first and second thermally conductive contacts at least partially engage one another when at least a portion of the first thermally conductive contact reaches a predetermined temperature.

29. The system of claim 17, wherein the material is a shape memory alloy.

30. The system of claim 29, wherein the shape memory alloy is selected from the group consisting of nickel-titanium, copper-zinc-aluminum, and iron-manganese-silicon.

31. The system of claim 17, wherein switch is comprised of two metals having different thermal coefficients of expansion.

32. The system of claim 31, wherein the two metals are selected from the group of pairs consisting of aluminum and nickel, zinc and nickel, zinc and aluminum, copper and iron, copper and molybdenum, and aluminum and iron.
